(19) United States
(12) Patent Application Publication
(10) Pub. No.: US 2010/0307574 A1
(43) Pub. Date: Dec. 9, 2010

(54) SOLAR CELL AND MANUFACTURING METHOD THEREOF

(75) Inventors: Mitsuhiro Matsumoto, Gifu-shi (JP); Kazuya Murata, Ampachi-gun (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/793,982

(22) Filed: Jun. 4, 2010

(30) Foreign Application Priority Data
Jun. 4, 2009 (JP) 2009-135396

(51) Int. Cl. H01L 31/0288

(52) U.S. Cl. 136/255

(57) ABSTRACT

A solar cell comprises a p-type layer (30), an i-type layer (32), and an n-type layer (34), and the p-type layer (30) comprises a high-absorption amorphous silicon carbide layer (30a), a silicon layer (30b) substantially not doped with a p-type dopant, and a buffer layer (30c) formed between the silicon layer (30b) and the i-type layer (32).

### CROSS-REFERENCE TO RELATED APPLICATIONS

The entire disclosure of Japanese Patent Application No. 2009-135396 filed on Jun. 4, 2009, including specification, claims, drawings, and abstract, is incorporated herein by reference in its entirety.

### BACKGROUND

1. Technical Field

The present invention relates to a solar cell and a manufacturing method of a solar cell.

2. Related Art

Solar cells are known in which polycrystalline silicon, microcrystalline silicon, or amorphous silicon is used. In particular, a solar cell in which microcrystalline or amorphous silicon thin films are layered has attracted much attention in view of resource consumption, reduction of cost, and improvement in efficiency.

In general, a thin film solar cell is formed by sequentially layering a first electrode, one or more semiconductor thin film photoelectric conversion cells, and a second electrode over a substrate having an insulating surface. Each solar cell unit is formed by layering a p-type layer, an i-type layer, and an n-type layer from a side of incidence of light.

As a method of improving the conversion efficiency of the thin film solar cell, a method is known in which two or more types of photoelectric conversion cells are layered in the direction of light incidence. A first solar cell unit having a photoelectric conversion layer with a wider band gap is placed on the side of light incidence of the thin film solar cell, and then, a second solar cell unit having an photoelectric conversion layer having a narrower band gap than the first solar cell unit is placed. With this configuration, photoelectric conversion is enabled for a wide wavelength range of the incident light, and the conversion efficiency of the overall device can be improved.

For example, a structure is known in which an amorphous silicon (a-Si) solar cell unit is set as a top cell and a microcrystalline silicon (μc-Si) solar cell unit is set as a bottom cell.

In order to improve the conversion efficiency of the thin film solar cell, it is necessary to optimize the characteristics of the thin films of the solar cell, and improve an open voltage Voc, a short-circuit current density Jsc, and a fill factor FF.

### SUMMARY

According to one aspect of the present invention, there is provided a solar cell comprising a p-type layer, an i-type amorphous silicon layer layered over the p-type layer, and an n-type silicon layer layered over the i-type amorphous silicon layer, wherein the p-type layer comprises a high-concentration amorphous silicon carbide layer doped with a p-type dopant, a silicon layer formed at a side nearer to the i-type amorphous silicon layer than is the high-concentration amorphous silicon carbide layer and substantially not doped with the p-type dopant, and a buffer layer formed between the silicon layer and the i-type amorphous silicon layer.

### BRIEF DESCRIPTION OF THE DRAWINGS

Preferred embodiments of the present invention will be described in further detail based on the following drawings, wherein:

FIG. 1 is a diagram showing a structure of a tandem-type solar cell in preferred embodiments of the present invention; and

FIG. 2 is a diagram showing a structure of an a-Si unit of the tandem-type solar cell in the preferred embodiments of the present invention.

### DETAILED DESCRIPTION

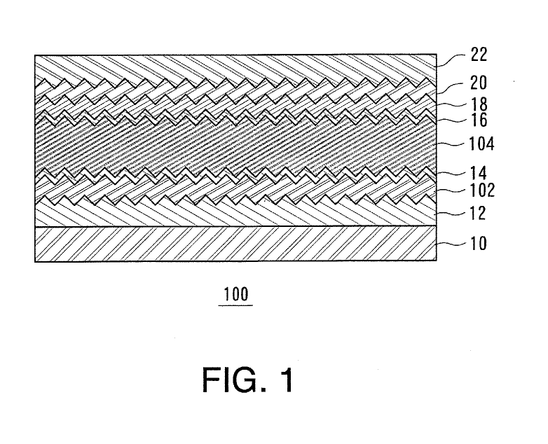

FIG. 1 is a cross sectional diagram showing a structure of a tandem-type solar cell 100 in preferred embodiments of the present invention. The tandem-type solar cell 100 in the present embodiments has a structure in which a transparent insulating substrate 10 is set at a light incidence side, and a transparent conductive film 12, an amorphous silicon (a-Si) (photoelectric conversion) unit 102 functioning as a top cell and having a wide band gap, an intermediate layer 14, a microcrystalline silicon (μc-Si) (photoelectric conversion) unit 104 functioning as a bottom cell and having a narrower band gap than the a-Si unit 102, a first backside electrode layer 16, a second backside electrode layer 18, a filler 20, and a protective film 22 are layered from the light incidence side.

A structure and a method of manufacturing the tandem-type solar cell 100 in the preferred embodiments of the present invention will now be described. As the tandem-type solar cell 100 in the present embodiments has a characteristic in a p-type layer included in the a-Si unit 102, the p-type layer in the a-Si unit 102 will be particularly described in detail.

As the transparent insulating substrate 10, a material having light transmittance at least in a visible light wavelength region such as, for example, a glass substrate, a plastic substrate, or the like, may be used. The transparent conductive film 12 is formed over the transparent insulating substrate 10. For the transparent conductive film 12, it is preferable to use at least one of or a combination of a plurality of transparent conductive oxides (TCO) in which tin (Sn), antimony (Sb), fluorine (F), aluminum (Al), or the like is doped into tin oxide (SnO₂), zinc oxide (ZnO), indium tin oxide (ITO), or the like. In particular, zinc oxide (ZnO) is preferable because it has a high light transmittance, a low resistivity, and a high plasma endurance characteristic. The transparent conductive film 12 can be formed, for example, through sputtering. A thickness of the transparent conductive film 12 is preferably set in a range of greater than or equal to 0.5 μm and less than or equal to 5 μm. In addition, it is preferable to provide unevenness having a light confinement effect on a surface of the transparent conductive film 12.

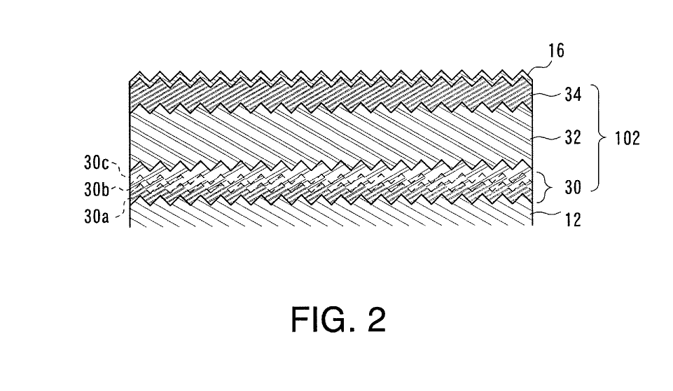

Silicon-based thin films, that is, a p-type layer 30, an i-type layer 32, and an n-type layer 34, are sequentially layered over the transparent conductive film 12, to form the a-Si unit 102. FIG. 2 shows an enlarged cross sectional view of the portion of the a-Si unit 102.

The a-Si unit 102 may be formed through plasma CVD in which mixture gas of silicon-containing gas such as silane (SiH₄), disilane (Si₂H₆), and dichlorsilane (SiH Cl₂), carbon-containing gas such as methane (CH₄), p-type dopant-containing gas such as diborane (B₂H₆), n-type dopant containing gas such as phosphine (PH₃), and dilution gas such as hydrogen (H₂) is made into plasma and a film is formed.

For the plasma CVD, for example, RF plasma CVD of 13.56 MHz is preferably applied. The RF plasma CVD may be of a parallel plate-type. Alternatively, a configuration may be employed in which a gas shower hole for supplying the mixture gas of the material is provided on a side of the parallel plate-type electrodes on which the transparent insulating substrate 10 is not placed. An input power density of the plasma is preferably greater than or equal to 5 mW/cm² and less than or equal to 100 mW/cm².

In general, the p-type layer 30, the i-type layer 32, and the n-type layer 34 are formed in different film formation chambers. The film formation chamber can be vacuumed using a vacuum pump, and an electrode for the RF plasma CVD is built into the film formation chamber. In addition, a transporting device of the transparent insulating substrate 10, a power supply and a matching device for the RF plasma CVD, pipes for supplying gas, etc. are provided.

The p-type layer 30 will be described later with reference to each embodiment. For the i-type layer 32, a non-doped amorphous silicon film formed over the p-type layer 30 and having a thickness of greater than or equal to 50 nm and less than or equal to 500 nm is employed. A film characteristic of the i-type layer 32 can be changed by adjusting the mixture ratios of silicon-containing gas and dilution gas, pressure, and plasma generating high-frequency power. In addition, the i-type layer 32 forms a power generation layer of the a-Si unit 102. For the n-type layer 34, an n-type amorphous silicon layer (n-type a-Si:H) or an n-type microcrystalline silicon layer (n-type μc-Si:H) formed over the i-type layer 32, doped with an n-type dopant (such as phosphorus), and having a thickness of greater than or equal to 10 nm and less than or equal to 100 nm is employed. The film characteristic of the n-type layer 34 can be changed by adjusting the mixture ratios of the silicon-containing gas, carbon-containing gas, n-type dopant-containing gas, and dilution gas, pressure, and plasma generating high-frequency power.

The intermediate layer 14 is formed over the a-Si unit 102. For the intermediate layer 14, it is preferable to use the transparent conductive oxide (TCO) such as zinc oxide (ZnO) and silicon oxide (SiOx). In particular, it is preferable to use zinc oxide (ZnO) or silicon oxide (SiOx) doped with magnesium Mg. The intermediate layer 14 may be formed, for example, through sputtering. A thickness of the intermediate layer 14 is preferably in a range of greater than or equal to 10 nm and less than or equal to 200 nm. Alternatively, it is also possible to not provide the intermediate layer 14.

The μc-Si unit 104 in which a p-type layer, an i-type layer, and an n-type layer are sequentially layered is formed over the intermediate layer 14. The μc-Si unit 104 may be formed through plasma CVD in which mixture gas of silicon-containing gas such as silane (SiH₄), disilane (Si₂H₆), dichlorsilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) is made into plasma and a film is formed.

Similar to the a-Si unit 102, for the plasma CVD, for example, an RF plasma CVD of 13.56 MHz is preferably applied. The RF plasma CVD may be of the parallel plate-type. Alternatively, a configuration may be employed in which a gas shower hole for supplying the mixture gas of the material is provided on a side of the parallel plate-type electrode on which the transparent insulating substrate 10 is not placed. The input power density of the plasma is preferably set to greater than or equal to 5 mW/cm² and less than or equal to 100 mW/cm².

For example, the μc-Si unit 104 is formed by layering a p-type microcrystalline silicon layer (p-type μc-Si:H) having a thickness of greater than or equal to 5 nm and less than or equal to 50 nm and doped with boron, a non-doped i-type microcrystalline silicon layer (i-type μc-Si:H) having a thickness of greater than or equal to 0.5 μm and less than or equal to 5 μm, and an n-type microcrystalline silicon layer (n-type μc-Si:H) having a thickness of greater than or equal to 5 nm and less than or equal to 50 nm and doped with phosphorus.

The unit is not limited to the μc-Si unit 104, and any unit may be used so long as the i-type microcrystalline silicon layer (i-type μc-Si:H) is used as a power generation layer.

A layered structure of a reflective metal and a transparent conductive oxide (TCO) is formed over the μc-Si unit 104 as the first backside electrode layer 16 and the second backside electrode layer 18. As the first backside electrode layer 16, a metal such as silver (Ag) and aluminum (Al) can be used. As the second backside electrode layer 18, a transparent conductive oxide (TCO) such as tin oxide (SnO₂), zinc oxide (ZnO), and indium tin oxide (Ito) is used. The TCO may be formed, for example, through sputtering. The first backside electrode layer 16 and the second backside electrode layer 18 are preferably formed to a total thickness of approximately 1 μm. In addition, it is preferable to form unevenness on the surface of at least one of the first backside electrode layer 16 and the second backside electrode layer 18, for improving the light confinement effect.

The surface of the second backside electrode layer 18 is covered with the protective film 22 by the filler 20. The filler 20 and the protective film 22 may be formed of a resin material such as EVA and polyimide. With such a configuration, it is possible to prevent intrusion of moisture or the like into the power generation layer of the tandem-type solar cell 100.

Alternatively, a YAG laser (with a basic wave of 1064 nm and second harmonics of 532 nm) may be used to separate and pattern the transparent conductive film 12, the a-Si unit 102, the intermediate layer 14, the μc-Si unit 104, the first backside electrode layer 16, and the second backside electrode layer 18, to achieve a structure in which a plurality of cells are connected in series.

The basic structure of the tandem-type solar cell 100 in the preferred embodiments of the present invention has been described. The structure of the p-type layer 30 in each preferred embodiment will now be described.

### First Preferred Embodiment

The p-type layer 30 is formed over the transparent conductive film 12. The p-type layer 30 includes an amorphous silicon carbide layer in which an absorption coefficient with respect to light of a particular wavelength changes with an increase in the thickness from the transparent conductive film 12 toward the i-type layer 32. A reference wavelength for the particular wavelength may be 600 nm.

More specifically, for example, because the absorption coefficient of the amorphous silicon carbide layer changes according to the doping concentration of the p-type dopant, the doping concentration of the p-type dopant may be set to become higher as the distance from the i-type layer 32 is increased. In this case, the doping concentration of the p-type dopant may be stepwise increased or continuously increased as the distance from the i-type layer 32 is increased.

In the case where the doping concentration is to be stepwise increased, first, a high-absorption amorphous silicon carbide layer 30a doped with the p-type dopant (such as boron) in a first doping concentration is formed over the transparent conductive film 12. Then, a low-absorption amorphous silicon carbide layer 30b doped with the p-type dopant (such as boron) in a second doping concentration lower than the first doping concentration may be formed over the high-absorption amorphous silicon carbide layer 30a. The second doping concentration is set to be ⅕ to 1/10 of the first doping concentration.

In this case, in the plasma CVD, while the plasma is being generated, the mixture ratios of the silicon-containing gas, carbon-containing gas, p-type dopant-containing gas, and dilution gas, pressure, and plasma generating high-frequency power may be adjusted, to consecutively form the high-absorption amorphous silicon carbide layer 30a and the low-absorption amorphous silicon carbide layer 30b. With this configuration, a plasma generated initial layer which adversely affects the power generation would not be formed at the interface between the high-absorption amorphous silicon carbide layer 30a and the low-absorption amorphous silicon carbide layer 30b, and the open voltage Voc and the fill factor FF of the solar cell can be improved.

Alternatively, it is also possible to stepwise form the low-absorption amorphous silicon carbide layer 30b by temporarily stopping the plasma after the high-absorption amorphous silicon carbide layer 30a is formed, adjusting the mixture ratios of the silicon-containing gas, carbon-containing gas, p-type dopant-containing gas, and dilution gas, pressure, and plasma generating high-frequency power, and again generating the plasma. In this case, the doping concentrations of the high-absorption amorphous silicon carbide layer 30a and the low-absorption amorphous silicon carbide layer 30b can be easily controlled, and there is an advantage that the change of the doping concentration between the high-absorption amorphous silicon carbide layer 30a and the low-absorption amorphous silicon carbide layer 30b is made abrupt. In particular, by exhausting the film formation device to vacuum before the mixture ratios of the mixture gas are adjusted, it is possible to remove the influence of the p-type dopant-containing gas remaining in the film formation chamber.

When the doping concentration of the amorphous silicon carbide layer is to be continuously changed, the doping concentration of the amorphous silicon carbide layer at the side near the i-type layer 32 is set in a range of ⅕ to 1/10 of the doping concentration of the amorphous silicon carbide layer at the side near the transparent conductive film 12.

In this case, in the plasma CVD, while the plasma is being generated, the mixture ratios of the silicon-containing gas, carbon-containing gas, p-type dopant-containing gas, and dilution gas, pressure, and plasma generating high-frequency power may be adjusted.

In addition, in order to adjust the band gap and avoid influences of plasma during formation of the i-type layer 32, a buffer layer 30c made of amorphous silicon carbide or microcrystalline silicon carbide is formed over the low-absorption amorphous silicon carbide layer 30b.

When the buffer layer 30c is formed, it is preferable to temporarily stop plasma after the low-absorption amorphous silicon carbide layer 30b is formed, stop the supply of the p-type dopant-containing gas, adjust the mixture ratios of the mixture gas, pressure, and plasma generating high-frequency power, and then generate plasma again to stepwise form the buffer layer 30c. In this case, by stopping only the plasma while maintaining supply of gas to transition from the film formation of the low-absorption amorphous silicon carbide layer 30b to the film formation of the buffer layer 30c, it is possible to prevent detachment of hydrogen from the surface of the low-absorption amorphous silicon carbide layer 30b, and to reduce a deficiency density at the interface between the low-absorption amorphous silicon carbide layer 30b and the buffer layer 30c. With this configuration, the open voltage Voc of the solar cell can be improved. In addition, the change of the doping concentration between the doped low-absorption amorphous silicon carbide layer 30b and the non-doped buffer layer 30c can be set to be abrupt.

Alternatively, it is also possible to employ a configuration where, in the formation of the buffer layer 30c, after the low-absorption amorphous silicon carbide layer 30b is formed, the transparent insulating substrate 10 is moved to the film formation chamber for forming the i-type layer 32, and the buffer layer 30c is formed. In this manner, by forming the buffer layer 30c in the film formation chamber to which the p-type dopant-containing gas is not supplied, it is possible to set the change of the doping concentration between the doped low-absorption amorphous silicon carbide layer 30b and the non-doped buffer layer 30c to be abrupt, and to reduce the deficiency density at the interface between the low-absorption amorphous silicon carbide layer 30b and the buffer layer 30c. With such a configuration, the open voltage Voc of the solar cell can be improved.

In the case of the first preferred embodiment, it is preferable to set the thickness of the high-absorption amorphous silicon carbide layer 30a or the thickness of the buffer layer 30c to be greatest in the p-type layer 30. Moreover, it is preferable that the thickness of the low-absorption amorphous silicon carbide layer 30b be lowest in the p-type layer 30. The thicknesses of the high-absorption amorphous silicon carbide layer 30a, the low-absorption amorphous silicon-carbide layer 30b, and the buffer layer 30c can be adjusted by adjusting the film formation times of the layers.

### Second Preferred Embodiment

The p-type layer 30 is formed over the transparent conductive film 12, and has a layered structure of an amorphous silicon carbide layer 30a doped with a p-type dopant (such as boron), a silicon layer 30b not doped with a p-type dopant, and a buffer layer 30c not doped with a p-type dopant.

First, the high-absorption amorphous silicon carbide layer 30a doped with a p-type dopant (such as boron) in a first doping concentration is formed over the transparent conductive film 12.

Then, the silicon layer 30b not doped with the p-type dopant (such as boron) is formed over the high-absorption amorphous silicon carbide layer 30a. Here, the condition of “not doped with p-type dopant” means that the layer is formed substantially without the supply of p-type dopant-containing gas.

In this case, in the plasma CVD, while the plasma is being generated, the mixture ratios of the silicon-containing gas, carbon-containing gas, p-type dopant-containing gas, and dilution gas, pressure, and plasma generating high-frequency power are adjusted, to consecutively form the high-absorption amorphous silicon carbide layer 30a and the silicon layer 30b. For example, after the silicon-containing gas, carbon-containing gas, p-type dopant-containing gas, and dilution gas are supplied and the high-absorption amorphous silicon carbide layer 30a is formed, the supply of the carbon-containing gas and p-type dopant-containing gas is stopped, to form the silicon layer 30b.

The silicon layer 30b is formed in a condition where an amorphous silicon layer or a microcrystalline silicon layer is formed. In other words, it is preferable to form the silicon layer 30b under a condition where the microcrystalline silicon is formed by adjusting the mixture ratios of the silicon-containing gas and the dilution gas (hydrogen), but, because the silicon layer 30b is very thin, the silicon layer 30b may be in a state of amorphous silicon.

With this configuration, the deficiency density which adversely affects the power generation around the interface of the high-absorption amorphous silicon carbide layer 30a and the silicon layer 30b can be reduced. In addition, the thickness of the high-absorption amorphous silicon carbide layer 30a which substantially becomes the p layer can be reduced. Therefore, the open voltage Voc, the short-circuit current density Jsc, and the fill factor FF of the solar cell can be improved.

Alternatively, it is also possible to stepwise form the silicon layer 30b by temporarily stopping plasma after the high-absorption amorphous silicon carbide layer 30a is formed, adjusting the mixture ratios of the silicon-containing gas, the carbon-containing gas, the p-type dopant-containing gas, and the dilution gas, pressure, and plasma generating high-frequency power, and then generating the plasma again. For example, the plasma may be temporarily stopped after the silicon-containing gas, the carbon containing gas, the p-type dopant-containing gas, and the dilution gas are supplied and the high-absorption amorphous silicon carbide layer 30a is formed, the supply of the carbon-containing gas and the p-type dopant-containing gas may be stopped to adjust the gas, and the plasma may be generated again, to form the silicon layer 30b.

In this case also, the deficiency density which adversely affects the power generation around the interface of the high-absorption amorphous silicon carbide layer 30a and the silicon layer 30b can be reduced. In addition, the thickness of the high-absorption amorphous silicon carbide layer 30a which substantially becomes the p layer can be reduced. Therefore, the open voltage Voc, the short-circuit current density Jsc, and the fill factor FF of the solar cell can be improved.

Furthermore, the doping concentrations of the high-absorption amorphous silicon carbide layer 30a and the silicon layer 30b can be easily controlled, and there is an advantage that the change of the doping concentration between the high-absorption amorphous silicon carbide layer 30a and the silicon layer 30b can be set to be abrupt. In particular, by exhausting the film formation device to vacuum before the mixture ratios of the mixture gas are adjusted, it is possible to remove the influence of the p-type dopant-containing gas remaining in the film formation chamber.

In addition, in order to adjust the band gap and avoid influences of plasma during formation of the i-type layer 32, a buffer layer 30c made of amorphous silicon carbide or microcrystalline silicon carbide is formed over the silicon layer 30b.

When the buffer layer 30c is formed, it is preferable to temporarily stop the plasma after the silicon layer 30b is formed, adjust the amount of supply of the carbon-containing gas, adjust the mixture ratios of the mixture gas, the pressure, and the plasma generating high-frequency power, and generate the plasma again, to form the buffer layer 30c. In this case, by transitioning from the formation of the silicon layer 30b to the formation of the buffer layer 30c while stopping only the plasma and not the supply of gas, it is possible to prevent detachment of hydrogen from the surface of the silicon layer 30b, and to reduce the deficiency density at the interface between the silicon layer 30b and the buffer layer 30c. With this configuration, the open voltage Voc of the solar cell can be improved.

Alternatively, when the silicon layer 30b or the buffer layer 30c is formed, the transparent insulating substrate 10 may be moved to the film formation chamber for forming the i-type layer 32 and the silicon layer 30b or the buffer layer 30c may be formed. In this manner, by forming the silicon layer 30b or the buffer layer 30c in the film formation chamber to which no p-type dopant-containing gas is supplied, it is possible to prevent capturing of the p-type dopant remaining in the film formation chamber by the silicon layer 30b or the buffer layer 30c, and to reliably reduce the doping concentration of the p-type dopant. With this configuration, the open voltage Voc of the solar cell can be improved.

When the buffer layer 30c made of the microcrystalline silicon carbide is layered over the silicon layer 30b, heating of the buffer layer 30c causes a new crystal nucleus to be generated and the characteristic of the film to be changed, resulting in a narrower band gap and a higher absorption coefficient of the light, and consequently a higher absorption loss of light. Therefore, it is more preferable that the buffer layer 30c be made of amorphous silicon carbide. With such a configuration, the characteristic change in the buffer layer 30c by heating is not caused, and the conversion efficiency of the solar cell can be further improved.

In the case of the second preferred embodiment also, it is preferable that the thickness of the high-absorption amorphous silicon carbide layer 30a or the thickness of the buffer layer 30c be set to be greatest in the p-type layer. In addition, it is preferable to set the silicon layer 30b to be thinnest in the p-type layer 30. The thicknesses of the high-absorption amorphous silicon carbide layer 30a, the silicon layer 30b, and the buffer layer 30c can be adjusted by adjusting the film formation times of the layers.

### EXAMPLES

Examples and comparative examples of the tandem-type solar cell 100 to which the p-type layer 30 of the above-described preferred embodiments is applied will now be described. Examples 1-4 and Comparative Example 1 show a dependency of the characteristic of the solar cell on the thickness of the p-type layer 30. Examples 5 and 6 and Comparative Example 2 show dependency of the characteristic of the solar cell on presence/absence of the silicon layer 30b and a combination with the buffer layer 30c.

### Examples 1-4 and Comparative Example 1

As the transparent insulating substrate 10, a glass substrate having a size of 33 cm×43 cm and a thickness of 4 mm was used. Over the transparent insulating substrate 10, a layer of SnO₂ having a thickness of 600 nm and having uneven shapes on the surface was formed through thermal CVD as the transparent conductive film 12. Then, the transparent conductive film 12 was patterned by a YAG laser in a strap shape. As the YAG laser, a YAG laser having a wavelength of 1064 nm, an energy density of 13 J/cm³, and a pulse frequency of 3 kHz was used.

Then, the high-absorption amorphous silicon carbide layer 30a, the low-absorption amorphous silicon carbide layer 30b, and the buffer layer 30c in the above-described first preferred embodiment were formed with the film formation conditions as shown in TABLE 1. The i-type layer 32 and the n-type layer 34 of the a-Si unit 102 were formed with the film formation conditions shown in TABLE 2, and the p-type layer, the i-type layer, and the n-type layer of the μc-Si unit 104 were formed with the conditions shown in TABLE 3.

TABLE 1

| | SUBSTRATE | GAS FLOW | REACTION | |
|---|---|---|---|---|
| | TEMPERATURE | RATE | PRESSURE | RF POWER |
| LAYER | (° C.) | (sccm) | (Pa) | (W) |
| HIGH-CONCENTRATION | 180 | SiH₄: 40 | 80 | 30 |
| AMORPHOUS SILICON | | CH₄: 80 | | |
| CARBIDE LAYER 30a | | B₂H₆: 0.12 | | |
| | | H₂: 400 | | |
| LOW-CONCENTRATION | 180 | SiH₄: 40 | 80 | 30 |
| AMORPHOUS SILICON | | CH₄: 80 | | |
| CARBIDE LAYER 30b | | B₂H₆: 0.01 | | |
| | | H₂: 400 | | |
| BUFFER LAYER 30c | 180 | SiH₄: 20 | 80 | 30 |
| | | CH₄: 10 | | |
| | | H₂: 2000 | | |

TABLE 2

| | SUBSTRATE | GAS FLOW | REACTION | | |
|---|---|---|---|---|---|
| | TEMPERATURE | RATE | PRESSURE | RF POWER | THICKNESS |
| LAYER | (° C.) | (sccm) | (Pa) | (W) | (nm) |
| i-TYPE | 200 | SiH₄: 300 | 106 | 20 | 250 |
| LAYER | | H₂: 2000 | | | |
| n-TYPE | 180 | SiH₄: 300 | 133 | 20 | 25 |
| LAYER | | H₂: 2000 | | | |
| | | PH₃: 5 | | | |

TABLE 3

| | SUBSTRATE | GAS FLOW | REACTION | | |
|---|---|---|---|---|---|
| | TEMPERATURE | RATE | PRESSURE | RF POWER | THICKNESS |
| LAYER | (° C.) | (sccm) | (Pa) | (W) | (nm) |
| p-TYPE | 180 | SiH₄: 10 | 106 | 10 | 10 |
| LAYER | | H₂: 2000 | | | |
| | | B₂H₆: 3 | | | |
| i-TYPE | 200 | SiH₄: 100 | 133 | 20 | 2000 |
| LAYER | | H₂: 2000 | | | |
| n-TYPE | 200 | SiH₄: 10 | 133 | 20 | 20 |
| LAYER | | H₂: 2000 | | | |
| | | PH₃: 5 | | | |

Then, the YAG laser was radiated on a position aside from the patterning position of the transparent conductive film 12 by 50 μm, to pattern the a-Si unit 102 and the μ-Si unit 104 in a strip shape. As the YAG laser, a YAG laser having an energy density of 0.7 J/cm³ and a pulse frequency of 3 kHz was used.

An Ag electrode was then formed as the first backside electrode layer 16 through sputtering and a ZnO film was formed as the second backside electrode layer 18 through sputtering. YAG laser was radiated at a position aside from the patterning position of the a-Si unit 102 and the μc-Si unit 104 by 50 μm, to pattern the first backside electrode layer 16 and the second backside electrode layer 18 in a strip shape. As the YAG laser, a YAG laser having an energy density of 0.7 J/cm³ and a pulse frequency of 4 kHz was used.

In this process, the high-absorption amorphous silicon carbide layer 30a, the low-absorption amorphous silicon carbide layer 30b, and the buffer layer 30c were formed in thicknesses as shown in TABLE 4, to obtain the structures of Examples 1-4. In addition, a structure in which the low-absorption amorphous silicon carbide layer 30b was not formed and the buffer layer 30c was directly formed over the high-absorption amorphous silicon carbide layer 30a was set as Comparative Example 1.

TABLE 4

| | HIGH-CONCENTRATION | LOW-CONCENTRATION | BUFFER |
|---|---|---|---|
| | AMORPHOUS SILICON | AMORPHOUS SILICON | LAYER |
| | CARBIDE LAYER 30a | CARBIDE LAYER 30b | 30c |
| EXAMPLE 1 | 8 nm | 7 nm | 5 nm |
| EXAMPLE 2 | 7 nm | 3 nm | 6 nm |
| EXAMPLE 3 | 7 nm | 3 nm | 10 nm |
| EXAMPLE 4 | 3 nm | 7 nm | 10 nm |
| COMPARATIVE | 10 nm | NONE | 10 nm |
| EXAMPLE 1 | | | |

TABLE 5 shows the open voltage Voc, the short-circuit current density Jsc, the fill factor FF, and the efficiency of each of the tandem-type solar cells 100 of Examples 1-4 and Comparative Example 1.

TABLE 5

| | OPEN | SHORT-CIRCUIT | | EFFI- |
|---|---|---|---|---|
| | VOLTAGE | CURRENT | | CIENCY |
| | Voc | DENSITY Jsc | FF | η |
| EXAMPLE 1 | 1 | 1.03 | 0.98 | 1.01 |
| EXAMPLE 2 | 1.01 | 1.02 | 1 | 1.03 |
| EXAMPLE 3 | 1.03 | 1.01 | 1.01 | 1.05 |
| EXAMPLE 4 | 1.02 | 1.02 | 1.01 | 1.05 |
| COMPARATIVE | 1 | 1 | 1 | 1 |
| EXAMPLE 1 | | | | |

By setting the thickness of the high-absorption amorphous silicon carbide layer 30a to be greatest in the p-type layer 30 as in Examples 1 and 2, it was possible to particularly improve the short-circuit current density Jsc and also the efficiency η compared to the Comparative Example 1. In addition, by setting the low-absorption amorphous silicon carbide layer 30b to be thinnest in the p-type layer 30, it was possible to improve both the open voltage Voc and the short-circuit current density Jsc, and to improve the efficiency η compared to the other configurations.

In addition, by setting the thickness of the buffer layer 30c to be greatest in the p-type layer 30 as in Examples 3 and 4, it was possible to improve all of the open voltage Voc, the short-circuit current density Jsc, and the fill factor FF, and the efficiency η compared to the Comparative Example 1. In addition, when the low-absorption amorphous silicon carbide layer 30b is set to be thinnest in the p-type layer 30, the highest improvement in the efficiency η was achieved.

In Examples 1-4, the p-type amorphous silicon carbide layer was formed such that an absorption coefficient with respect to light of a wavelength of 600 nm is reduced toward the i-type layer. More specifically, the p-type amorphous silicon carbide layer was formed with the high-absorption amorphous silicon carbide layer 30a and the low-absorption amorphous silicon carbide layer 30b. In other words, the absorption coefficient of the high-absorption amorphous silicon carbide layer 30a was higher compared to the low-absorption amorphous silicon carbide layer 30b, and the ranges of the absorption coefficients were greater than or equal to 1.2×10⁴ cm⁻¹ and less than or equal to 3×10⁴ cm⁻¹ and greater than or equal to 6.0×10³ cm⁻¹ and less than or equal to 1.0×10⁴ cm⁻¹.

In the related art, it is known to set the absorption coefficient to be greater (band gap to be smaller) from the side of light incidence toward the i-type layer. In the present embodiment, on the other hand, in Example 3, the open voltage Voc was improved with the absorption coefficient becoming smaller from the side of light incidence toward the i-type layer. This can be deduced to be because the absorption of light by the low-absorption amorphous silicon carbide layer 30b is reduced and the amount of light reaching the i-type layer is increased. On the other hand, it can be deduced that, by providing the high-absorption amorphous silicon carbide layer 30a over the transparent conductive film 12, it is possible to prevent an increase in the connection resistance between the transparent conductive film 12 and the p-type amorphous silicon carbide layer.

A band gap Eₒₚₜ of the silicon carbide film and the silicon film can be determined in the following method. For example, as described in Japanese Journal of Applied Physics, Vol. 30, No. 5, May, 19991, pp. 1008-1014, an absorption coefficient spectrum of the silicon carbide film and the silicon film is determined and the optical band gap Eₒₚₜ is determined by (αhν)^{1/3} plotted based on the absorption spectrum. The light transmittance and reflectivity when the absorption spectrum is determined can be measured with, for example, U4100 manufactured by Hitachi High-Technologies Corporation. When the absorption coefficient spectrum is determined, it is preferable to evaluate a film formed to a thickness of 100 nm-300 nm over the glass substrate under the same conditions as the conditions when the solar cell element is formed, and the glass substrate used in this process may be, for example, #7059 glass or #1737 glass, both of which are manufactured by Corning Inc., or a clear glass having a thickness of less than or equal to 5 mm.

### Examples 5 and 6 and Comparative Example 2

The high-absorption amorphous silicon carbide layer 30a, the silicon layer 30b, and the buffer layer 30c in the above-described second preferred embodiment were formed with film formation conditions as shown in TABLE 6. TABLE 6 shows a case where the buffer layer 30c was formed as a microcrystalline silicon carbide layer and a case where the buffer layer 30c was formed as an amorphous silicon carbide layer. The i-type layer 32 and the n-type layer 34 of the a-Si unit 102 were formed with the film formation conditions shown in TABLE 2, and the p-type layer, the i-type layer, and the n-type layer of the μc-Si unit 104 were formed with the conditions shown in TABLE 3. The other formation methods were set identical to those of Examples 1-4.

TABLE 6

| | SUBSTRATE | GAS FLOW | REACTION | |
|---|---|---|---|---|
| | TEMPERATURE | RATE | PRESSURE | RF POWER |
| LAYER | (° C.) | (sccm) | (Pa) | (W) |
| HIGH-CONCENTRATION | 180 | SiH₄: 40 | 80 | 30 |
| AMORPHOUS SILICON | | CH₄: 80 | | |
| CARBIDE LAYER 30a | | B₂H₆: 0.12 | | |
| | | H₂: 400 | | |
| SILICON LAYER 30b | 180 | SiH₄: 20 | 80 | 30 |
| | | H₂: 2000 | | |
| BUFFER LAYER 30c | 180 | SiH₄: 20 | 80 | 30 |
| (MICROCRYSTALLINE | | CH₄: 10 | | |
| SILICON CARBIDE) | | H₂: 2000 | | |
| BUFFER LAYER 30c | 180 | SiH₄: 40 | 80 | 30 |
| (AMORPHOUS SILICON | | CH₄: 40 | | |
| CARBIDE) | | H₂: 120 | | |

In this process, the high-absorption amorphous silicon carbide layer 30a, the silicon layer 30b, and the buffer layer 30c were formed to thicknesses shown in TABLE 7, to obtain structures of Examples 5 and 6. Example 5 was a structure where the buffer layer 30c was formed as a microcrystalline silicon carbide layer and Example 6 was a structure where the buffer layer 30c was formed as an amorphous silicon carbide layer. In addition, a configuration where the silicon layer 30b was not formed and the buffer layer 30c was directly formed over the high-absorption amorphous silicon carbide layer 30a was set as Comparative Example 2.

TABLE 7

| | HIGH-CONCENTRATION | SILICON | BUFFER |
|---|---|---|---|
| | AMORPHOUS SILICON | LAYER | LAYER |
| | CARBIDE LAYER 30a | 30b | 30c |
| EXAMPLE 5 | 7 nm | 3 nm | 10 nm |
| EXAMPLE 6 | 7 nm | 3 nm | 10 nm |
| COMPARATIVE | 10 nm | NONE | 10 nm |
| EXAMPLE 2 | | | |

TABLE 8 shows initial characteristics of the open voltage Voc, the short-circuit current density Jsc, the fill factor FF, and the efficiency of each of the tandem-type solar cells 100 of Examples 5 and 6 and Comparative Example 2. TABLE 9 shows the open voltage Voc, the short-circuit current density Jsc, the fill factor FF, and efficiency after each of the tandem-type solar cells 100 of Examples 5 and 6 and Comparative Example 2 was annealed at 150° C. for 3 hours.

TABLE 8

| | OPEN | SHORT-CIRCUIT | | EFFI- |
|---|---|---|---|---|
| | VOLTAGE | CURRENT | | CIENCY |
| | Voc | DENSITY Jsc | FF | η |
| EXAMPLE 5 | 1.02 | 1.02 | 1.01 | 1.05 |
| EXAMPLE 6 | 1.02 | 1.02 | 1 | 1.04 |
| COMPARATIVE | 1 | 1 | 1 | 1 |
| EXAMPLE 2 | | | | |

TABLE 9

| | OPEN | SHORT-CIRCUIT | | EFFI- |
|---|---|---|---|---|
| | VOLTAGE | CURRENT | | CIENCY |
| | Voc | DENSITY Jsc | FF | η |
| EXAMPLE 5 | 1.02 | 0.99 | 1.01 | 1.02 |
| EXAMPLE 6 | 1.02 | 1.02 | 1.01 | 1.05 |
| COMPARATIVE | 1 | 1 | 1 | 1 |
| EXAMPLE 2 | | | | |

By providing the silicon layer 30b not doped with the p-type dopant between the high-absorption amorphous silicon carbide layer 30a and the buffer layer 30c as in Examples 5 and 6, it was possible to improve the open voltage Voc, the short-circuit current density Jsc, the fill factor FF, and the efficiency η compared to Comparative Example 2.

In particular, in the initial characteristic, Example 5 where the buffer layer 30c was formed as the microcrystalline silicon carbide layer was superior in the fill factor FF than Example 6 in which the buffer layer 30c was formed as the amorphous silicon carbide layer. After the annealing, on the other hand, the short-circuit current density Jsc of Example 5 where the buffer layer 30c was formed as the microcrystalline silicon carbide layer was reduced and the fill factor FF of Example 6 where the buffer layer 30c was formed as the amorphous silicon carbide layer was improved. As a result, the efficiency η was superior in Example 6 where the buffer layer 30c was formed as the amorphous silicon carbide layer than Example 5 where the buffer layer 30c was formed as the microcrystalline silicon carbide layer. This can be deduced to be because, when the buffer layer 30c formed as the microcrystalline silicon carbide layer is layered over the silicon layer 30b, a new crystal nucleus is generated in the buffer layer 30c, resulting in change in characteristic of the film and an increase in the absorption loss of light.

What is claimed is:

1. A solar cell comprising:
a p-type layer;
an i-type amorphous silicon layer layered over the p-type layer; and
an n-type silicon layer layered over the i-type amorphous silicon layer, wherein
the p-type layer comprises a high-concentration amorphous silicon carbide layer doped with a p-type dopant, a silicon layer formed at a side nearer to the i-type amorphous silicon layer than is the high-concentration amorphous silicon carbide layer and substantially not doped with the p-type dopant, and a buffer layer formed between the silicon layer and the i-type amorphous silicon layer.

2. The solar cell according to claim 1, wherein
a thickness of the high-concentration amorphous silicon carbide layer is greater than thicknesses of the silicon layer and the buffer layer.

3. The solar cell according to claim 1, wherein
a thickness of the buffer layer is greater than thicknesses of the silicon layer and the high-concentration amorphous silicon carbide layer.

4. The solar cell according to claim 1, wherein
a thickness of the silicon layer is less than thicknesses of the high-concentration amorphous silicon carbide layer and the buffer layer.

5. solar cell according to claim 2, wherein
the thickness of the silicon layer is less than the thicknesses of the high-concentration amorphous silicon carbide layer and the buffer layer.

6. The solar cell according to claim 3, wherein
the thickness of the silicon layer is less than the thicknesses of the high-concentration amorphous silicon carbide layer and the buffer layer.

7. The solar cell according to claim 1, wherein
the buffer layer comprises silicon carbide, and
the silicon layer has lower concentration of carbon atoms than the buffer layer, or is substantially not doped with carbon atoms.
